(19) United States
(12) Patent Application Publication
(10) Pub. No.: US 2025/0208580 A1
(43) Pub. Date: Jun. 26, 2025

(54) DEVICE FOR DETERMINING AN ACOUSTIC EVENT FOR A WATCH DIAL

(71) Applicant: ETA SA MANUFACTURE HORLOGÈRE SUISSE, Grenchen (CH)

(72) Inventors: Dominique DUBUGNON, Saint-Prex (CH); Pierpasquale TORTORA, Neuchâtel (CH); Sylvain HUOT-MARCHAND, Eschert (CH); Raphaël COURVOISIER, Corcelles (CH)

(73) Assignee: ETA SA MANUFACTURE HORLOGÈRE SUISSE, Grenchen (CH)

(21) Appl. No.: 18/954,734

(22) Filed: Nov. 21, 2024

(30) Foreign Application Priority Data
Dec. 22, 2023 (EP) 23220082.4

(51) Int. Cl. G04B 47/06; G04C 10/02; G04G 21/02; H04R 1/02

(52) U.S. Cl. CPC G04B 47/06; G04C 10/02; G04G 21/02; H04R 1/028

(57) ABSTRACT

A dial (2a, 2b) of a watch (1) including an autonomous device for determining an acoustic event (3). The dial includes a visible face (20a) and a hidden face (20b), the dial (2a, 2b) being formed by a stack (9a, 9b) of thin layers (10, 11, 12, 13, 14) of material extending between these two faces (20a, 20b), each of the layers (10, 11, 12, 13, 14) including one or more of the functional elements including: a receiver element (23) for receiving an acoustic wave originating from the watch (1); a module (4) for reporting the acoustic event; a stand-alone power supply unit (21); and a control unit (7) for managing the operation of the reporting module (4) and the at least one receiver element (23) for receiving at least one acoustic wave.

### CROSS REFERENCE TO RELATED APPLICATION

This application claims priority to European Patent Application No. 23220082.4 filed Dec. 22, 2023, the entire contents of which are incorporated herein by reference.

### TECHNICAL FIELD OF THE INVENTION

The present invention relates to a watch comprising a dial including a device for determining an acoustic event, which device is entirely autonomous.

### TECHNOLOGICAL BACKGROUND

Prior art documents describe electromechanical watches with hands, in which watches the hour hand and minute hand displaying the current time are driven by the gear trains of a mechanism of a horological movement. In this context, the operation of the mechanism can be disrupted by impacts to the watch. As a result, although the watch's internal clock provides an accurate indication of the current time, the hour and minute hands provide a distorted indication of this current time due to the effect of the external disturbance to the watch. It may therefore be necessary to resynchronise the position of the hour and minute hands.

In this context, it is understood that there is a need to find a solution that overcomes the drawbacks of the prior art.

### SUMMARY OF THE INVENTION

The aim of the invention is to overcome these drawbacks by proposing a watch provided with a dial comprising a device for determining an acoustic event, which device is autonomous and whose efficiency remains constant over time.

One aspect of the invention relates to a watch dial comprising an autonomous device for determining an acoustic event, such a dial comprising a visible face and a hidden face, said dial being formed by a stack of thin layers of material extending between these two faces, each of said layers comprising one or more of the functional elements included in said device:
at least one receiver element for receiving at least one acoustic wave originating from the watch;
a module for reporting the acoustic event;
a stand-alone power supply unit; and
   a control unit for managing the operation of said reporting module and said at least one receiver element for receiving at least one acoustic wave.

In other embodiments:
said at least one receiver element comprises a pressure microphone or a pressure-gradient microphone;
the module for reporting the acoustic event comprises at least one element capable of generating a light signal;
the module for reporting the acoustic event comprises at least one element capable of generating a vibration signal;
the module for reporting the acoustic event comprises at least one element capable of generating a sound signal;
the stack of thin layers of material comprises a first layer provided with the visible face of the dial and comprising said at least one receiver element and said at least one light source;
said at least one receiver element is arranged in a cavity formed in the hidden face of this dial;
said first layer is configured such that light radiation, in particular solar radiation, can fully or partially pass therethrough;
said first layer is wholly or partially transparent or translucent;
the stack of thin layers of material includes a second layer comprising a photovoltaic module constituting the stand-alone power supply unit;
the second layer comprises a substrate on which the photovoltaic module is printed;
said photovoltaic module is arranged on an active area of said second layer, said area being configured to receive light radiation originating from the first layer of the stack of thin layers of material;
the stack includes a third layer comprising an electrical energy accumulator constituting the stand-alone power supply unit;
the third layer comprises a substrate on which the electrical energy accumulator is printed;
the stack comprises a fourth layer forming a hidden face of the dial comprising the control unit;
the stack comprises a third layer comprising a hidden face of the dial comprising the control unit and an electrical energy accumulator constituting the stand-alone power supply unit;
the first layer is rigid compared to the other layers in the stack of thin layers of material, which are flexible;
said visible and hidden faces are flat or domed.

Another aspect of the invention relates to a watch comprising such a dial.

Advantageously, the watch comprises a mechanical, electronic or electromechanical horological movement.

### BRIEF DESCRIPTION OF THE FIGURES

The purposes, advantages and features of the watch according to the invention will appear more clearly in the following description which is given on the basis of at least one non-limiting embodiment shown by way of the drawings, in which:

FIG. 1 shows a perspective view of a watch comprising a dial provided with a device for determining an acoustic event, which device is autonomous and included in the watch, according to embodiments of the invention;

FIG. 2 shows an exploded view of a first alternative embodiment of the dial formed by a stack of four superimposed layers, said layers each comprising one or more component elements of the device for determining an acoustic event, according to a first embodiment of the invention;

FIG. 3 diagrammatically shows this first alternative embodiment of the dial provided with the autonomous device for determining an acoustic event, according to the first embodiment of the invention;

FIG. 4 shows an exploded view of a second alternative embodiment of the dial formed by a stack of three superimposed layers, said layers each comprising one or more component elements of the device for determining an acoustic event, according to a second embodiment of the invention; and

FIG. 5 diagrammatically shows this second alternative embodiment of the dial provided with the autonomous device for determining an acoustic event, according to the second embodiment of the invention.

### DETAILED DESCRIPTION OF THE INVENTION

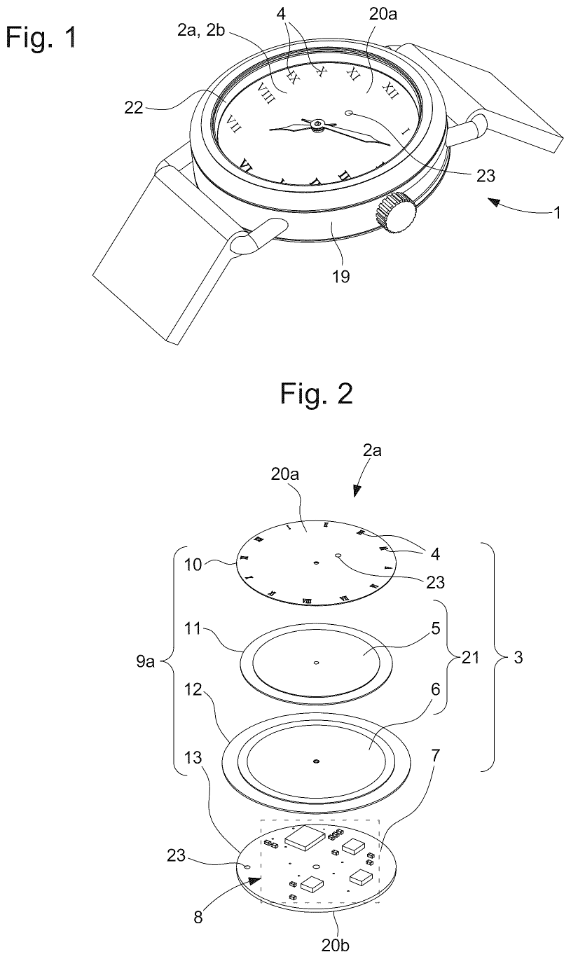

FIG. 1 diagrammatically shows a watch 1 comprising a case 19 with a middle to which a back and a crystal 22 are attached, a set of components forming a horological movement, and a dial 2a, 2b arranged between the horological movement and the crystal 22.

In a manner known to a person skilled in the art, the horological movement drives a set of hands comprising an hour hand, a minute hand and optionally a seconds hand. To this end, the dial 2a, 2b comprises a through-hole receiving the arbor of the hands. This dial 2a, 2b further comprises two faces 20a, 20b:
a so-called visible face 20a which is visible from the outside of the watch 1, also referred to as the “visible part” or “visible upper part” of this dial 2a, 2b; and
a so-called hidden face 20b arranged facing the horological movement in an enclosure of the case 19 of the watch 1, this face 20b being otherwise referred to as the “hidden part” or “hidden lower part” of this dial 2a, 2b.

Such a visible face 20a can comprise, in a non-limitative and non-exhaustive manner, at least one graphic representation such as:
a reference (or display) element such as, for example, a numeral, an index, a line or even a dot contributing, with or without the hands, to the display of a piece of horological information/a horological measurement or a piece of physical information/a physical measurement taken by a sensor or the like included in the movement;
an inscription, a pattern, a text, or a logo, etc.

This visible face 20a and this hidden face 20b are substantially flat and/or parallel and/or opposite each other. It should be noted that, in other alternative embodiments, the dial 2a, 2b can comprise a domed visible face and a hidden face which can be domed or flat. These faces 20a, 20b are also connected to each other by a peripheral wall of this dial 2a, 2b.

It should also be noted that in the embodiments illustrated in FIGS. 1 to 5, the dial 2a, 2b preferably has a circular shape. It is understood that the invention can also be implemented for dials 2a, 2b having other shapes such as, for example, a triangular shape or a shape similar to that of a quadrilateral.

In the embodiments of the invention, the horological movement is a mechanical movement. Alternatively, this movement can be an electromechanical movement. In the description below, reference will be made to a mechanical watch when its movement is mechanical, and to an electromechanical and electronic watch when their movements are electromechanical and electronic respectively.

With reference to FIGS. 2 and 4, such a dial 2a, 2b comprises an autonomous device 3 for determining an acoustic event. This determination device 3 comprises its own electrical power supply means as will be described hereafter. Such a device 3 for determining an acoustic event is said to be autonomous in particular relative to the movement of the watch 1 and in particular relative to the power source of this movement, for example when this source is an electrical power supply as in an electromechanical movement. In these circumstances, it is understood that the power used by this device 3 for determining an acoustic event is not to the detriment of the autonomy of the movement.

In this context, the dial 2a, 2b can be removably mounted in the watch 1, regardless of the type of watch 1. The only condition to be met is that the dial 2a, 2b includes this device 3 for determining an acoustic event, which is thus autonomous as regards the movement of the watch 1. This dial 2a, 2b is also referred to as an “autonomous dial” because it is not connected electrically to the movement of the watch 1.

This determination device 3 included in this dial 2a, 2b, comprises a module 4 for reporting the acoustic event, a stand-alone power supply unit 21, at least one receiver element 23 for receiving at least one acoustic wave, and a control unit 7.

In this device 3, the reporting module 4 comprises:
at least one element capable of generating a light signal 4, such as a light source 4 allowing the device 3 to broadcast a visual message in relation to the determined acoustic event;
at least one element capable of generating a vibration signal, such as a piezoelectric vibrator, a vibrator comprising an ERM motor (eccentric rotating mass vibration motor) or an LRA motor (linear resonant actuator vibration motor), allowing the device 3 to broadcast a message in the form of vibrations in relation to the determined acoustic event; and/or
at least one element capable of generating a sound signal, such as a loudspeaker, allowing the device 3 to broadcast an audible message in relation to the determined acoustic event.

As mentioned above, said at least one light source 4 is implemented in particular to help display a visual message relating to the determined acoustic event. Each light source 4 can correspond to any light-emitting element selected from a non-exhaustive and non-limiting list that includes:
a Light-Emitting Capacitor or LEC;
a light-emitting diode of the LED (Light-Emitting Diode) type, OLED (Organic Light-Emitting Diode) type, AMOLED (Active-Matrix Organic Light-Emitting Diode) type or QLED (Quantum Light-emitting diode) type;
any light-emitting material activated by a local electric field;
any light-emitting material activated by an electric current;
any combination of these light-emitting elements.

It should be noted that this light source 4 can, in certain embodiments of the invention, be a light source 4 capable of forming an area light source. This makes it possible to give the area light source a predetermined shape, typically, without this being exhaustive or limiting, a shape relating to a graphic representation of a numeral, a letter, a logo or a text. It should also be noted that this light source 4 can produce light in any colour and/or in any direction.

In this device 3 for determining an acoustic event, said at least one acoustic wave receiver element 23 is configured to identify such a wave generated by the watch and in particular by a timepiece component and/or a timepiece mechanism of the movement of this watch 1.

In a non-limiting and non-exhaustive manner, this timepiece component can be:
an external timepiece component, such as a case, a middle, a dial, or a back, etc.;
a component of a horological movement such as an oscillating weight, a rotor, a barrel, a gear train, or a movement plate, etc.

In this watch, the timepiece mechanism is involved in measuring time, or in functions or complications. It can be a lever escapement, for example.

This receiver element 23 comprises at least one electro-acoustic transducer which is able to convert an acoustic wave into an electrical signal. This receiver element 23 can comprise at least one pressure microphone or pressure-gradient microphone generally provided with a diaphragm or with a piezoelectric element which is capable of deforming and/or moving under the effect of at least one acoustic signal.

Alternatively, this receiver element 23 can comprise at least one optical microphone. Such a microphone, which is described in more detail in the European patent document EP2338287B1, is a device that is able to convert an acoustic wave into an electrical signal using interferometry-based technology. Such a microphone in particular comprises a source of electromagnetic radiation, reflective elements such as mirrors, at least one detector for detecting this electromagnetic radiation and an interferometer such as a Fabry-Pérot interferometer or a Gires-Tournois etalon.

It should be noted that in another alternative embodiment, this receiver element 23 can comprise any combination of the following microphones: at least one pressure microphone, at least one pressure-gradient microphone and at least one optical microphone.

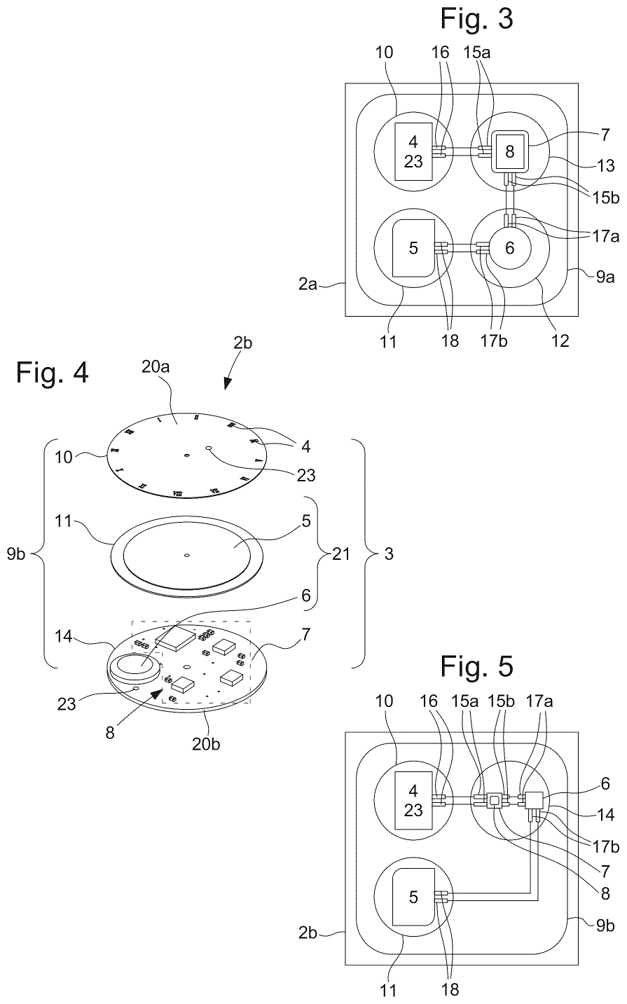

In this determination device 3, the stand-alone power supply unit 21 comprises an electrical energy accumulator 6 and a photovoltaic module 5 comprising at least one photovoltaic cell, also referred to as a solar cell. This photovoltaic module 5 is connected to the electrical energy accumulator 6 via connection elements denoted by the reference numerals 17b and 18 in FIGS. 3 and 5. This photovoltaic module 5 can comprise one or more unit cells of the heterojunction or multijunction type, connected in parallel or in series. Each photovoltaic cell of this module 5 can be made, in a manner known to a person skilled in the art, from copper-, indium-, gallium- and selenium-based semiconductor materials, from cadmium telluride-based semiconductor materials, from monocrystalline gallium arsenide-based semiconductor materials, from monocrystalline or polycrystalline silicon-based semiconductor materials, or from perovskite semiconductor materials. It should be noted that these examples are not limitative and that a person skilled in the art will be able to find the type of photovoltaic cell suitable for the invention.

In this device 3 for determining an acoustic event, the control unit 7, also referred to as a microcontroller, comprises an electronic circuit 8 including hardware resources, in particular at least one processor cooperating with memory elements as well as address, data and control buses. This control unit 7 is connected to the reporting module 4, to said at least one receiver element for receiving at least one acoustic wave 23 and to the stand-alone power supply unit 21. The memory elements of such a control unit 7 comprise an algorithm for determining an acoustic event.

This algorithm can be trained automatically, also known as machine learning, which is preferably supervised. More particularly, this is a learning algorithm for determining an acoustic event as a function of sound identity/signature characteristics derived from the processing of the acoustic signals and carried out by the control unit 7. Such an algorithm can comprise or implement at least one neural network and/or an analytical function and/or a principal of polynomial regression. For this purpose, the control unit 7, which is involved in implementing such training, includes training data pertaining to acoustic wave measurements and training data pertaining to determined/identified acoustic events experienced by the watch. The purpose of this training is to improve the algorithm and in particular the resulting model in order to minimise the error between “estimation and reality” in the context of evaluating a given acoustic event as a function of an acoustic wave measurement relating to this event.

It should be noted that such an algorithm, which is executed by the processor of this control unit 7, can also take into account other types of events in order to improve the determination of the acoustic event, on the basis of data from event sensors included in this determination device 3. These events can include, in a non-limiting and non-exhaustive manner: the detection of a particular brightness level in the environment of the watch 1, the detection of a particular visual object, or the detection of a movement made by a part of the user's body on which this watch 1 is included, etc. In this context, the event sensor of this determination device 3 comprises in particular and in a non-limiting and non-exhaustive manner:
a brightness sensor to detect the ambient brightness level;
a motion sensor for sensing a movement made by a part of the user's body comprising the watch 1, such as a gyroscopic and/or inertial sensor in the form of an electronic component of the gyroscopic and/or inertial electromechanical microsystem circuit type; and/or
a photographic-type optical sensor.

Furthermore, when the reporting module 4 comprises a plurality of light sources 4, the operation thereof can then be managed/controlled by the control unit 7 simultaneously and/or sequentially. Moreover, each light source 4 is managed/controlled separately by this control unit 7. In this context, the management of the operation of each light source 4 can consist, in a non-limiting and non-exhaustive manner, of carrying out the following operations: sequential switching on or off, simultaneous switching on or off of two or more light sources 4, flashing of one or more light sources 4, definition of a flashing frequency for each light source 4, a flashing duration for each light source 4, or a switching on or off duration for each light source 4, etc.

The memory elements of such a control unit 7 can further comprise an algorithm for managing the electrical energy accumulator 6, in particular for managing its recharging by the photovoltaic module 5 and for managing the electrical consumption of said reporting module 4 and of the receiver element 23.

As mentioned above, the autonomous device 3 for determining an acoustic event is thus included in the dial 2a, 2b. In this configuration, the component elements of this determination device 3, namely the reporting module 4, the electrical energy accumulator 6, the receiver element 23, the photovoltaic module 5, and the control unit 7, are included in one or more layers 10, 11, 12, 13, 14 forming this dial 2a, 2b.

With reference to FIGS. 2 to 5, this dial 2a, 2b is formed or constituted by a stack 9a, 9b of a plurality of thin layers 10, 11, 12, 13, 14, these layers 10, 11, 12, 13, 14 being joined together by a joining element such as an adhesive substance so as to unify them in order to obtain a stack 9a, 9b of monolithic thin layers thus forming a one-piece dial 2a, 2b. This joining element can also be a clip or a screw. Such layers 10, 11, 12, 13, 14 are superimposed in the stack 9a, 9b of layers, i.e. they are arranged one on top of the other in this dial 2a, 2b in a defined order. It should be noted that such a stack 9a, 9b of layers can also be referred to as an assembly of layers. In this stack 9a, 9b, the layers are substantially similar, having upper and lower surfaces of substantially the same area, thus helping to form the peripheral wall of the dial 2a, 2b, which has no relief.

It should be noted that these thin layers are layers that each have a micrometric thickness. More specifically, each layer can have a thickness of between 1 and 100 μm, preferably 2 μm, or more preferably 3 μm. Relative to the thickness of the dial 2a, 2b, it can be between 8 and 400 μm, preferably 6 μm, more preferably 12 μm, more preferably 100 μm, more preferably 200 μm or more preferably 300 μm.

Such a one-piece dial 2a, 2b also has the additional advantage of being able to be removably mounted in the case 19 of the watch 1, in addition to facilitating its integration in this case 19.

In a first alternative embodiment of this stack 9a of layers illustrated in FIG. 3, it is constituted by the following four successive thin layers 10, 11, 12, 13:
a first layer 10 forming/constituting the visible face 20a of the dial 2a including said at least one receiver element 23 and/or the reporting module 4;
a second layer 11 including the photovoltaic module 5;
a third layer 12 including an electrical energy accumulator 6, also referred to as a rechargeable battery; and
a fourth layer 13 forming the hidden face 20b of the dial 2a including said at least one receiver element 23 and/or the control unit 7.

The first layer 10 of this stack 9a is preferably rigid or semi-rigid compared with the second, third and fourth thin layers 11, 12, 13 which are preferably pliable or flexible. It is understood that such a first layer 10 contributes to the structural rigidity of the stack 9a of thin layers and thus of the dial 2a.

In this stack 9a, the first, second, third and fourth layers 10, 11, 12 and 13 each comprise an upper surface and a lower surface.

The first layer 10 is formed by a transparent, translucent, at least partially transparent, or at least partially translucent rigid or semi-rigid substrate. Such a substrate is made of a material with a transmittance for solar radiation, in particular ultraviolet radiation, also referred to as UVT (for “Ultra-Violet Transmission”) of between 65 and 95 percent. This transmittance is preferably 85 percent. Such a material can be transparent or translucent. This material can be, in a non-limiting and non-exhaustive manner, a polymer, glass or ceramic.

In this context, it is understood that this substrate is configured so that:
the light produced by said at least one light source of the reporting module 4 can escape to the outside of the dial 2a, 2b and thus of the watch 1; and
light from the environment of the watch 1 can penetrate the dial 2a, 2b towards the photovoltaic module 5 of the device 3 for determining an acoustic event, this light comprising solar radiation when it is of natural origin.

In other words, this transparent or translucent substrate is configured to allow the light, in particular solar radiation, capable of supplying the photovoltaic module 5 to pass therethrough so that the latter can convert the solar energy from this radiation into electrical energy.

This first layer 10 comprises the reporting module 4 which is arranged in the body of the substrate. In this configuration, the arrangement of the light source of this module 4 in this substrate is configured to ensure illumination of all or part of the visible face 20a of the dial 2a, for example, illumination of a graphic representation such as a reference element (or display) such as a numeral, an index, a line, a dot or illumination of one or more hands, or even illumination of all or part of the surface of the visible face of the dial 2a. In an alternative embodiment, this light source 4 can have a predetermined shape such as the shape of a numeral, a letter, an index, a line, a dot, a logo or even a text.

This illumination can be backlighting or semi-direct illumination when the light source 4 is arranged in a cavity defined in the substrate. More specifically, this cavity can be a blind opening made in the lower surface of this substrate. In this configuration, when the bottom of this cavity includes a graphic representation, the luminous radiation, or the light, produced by this light source 4 can escape to the outside of the dial 2a via the visible face 20a of this dial 2a, thus allowing at least one graphic representation to be viewed in the dark. In particular, the light radiation escaping from the visible face 20a draws the outline of this graphic representation. In this context, this graphic representation included in or on the upper surface or on the lower surface of the substrate forming the first layer 10, is preferably opaque, non-translucent or non-transparent.

This illumination can be direct illumination when the light source 4 is arranged in a cavity defined in the substrate. This cavity can be a blind opening made in the lower surface of this substrate, the bottom of which is devoid of any graphic representation. In this configuration, the luminous radiation, or light, produced by this light source 4 can escape through the bottom of this cavity towards the outside of the dial 2a and thus through the visible face 20a of this dial 2a.

This illumination can also be direct illumination when the light source 4 is arranged in a through-opening extending through the thickness of the substrate of the first layer 10, opening, at its two ends, respectively onto the upper and lower surfaces of this substrate. In this configuration, all or part of the light source 4 can project from the upper surface of this substrate and thus from the first layer 10 or from the visible face 20a of the dial 2a to form a graphic representation such as an index, a number, a dot, or a line, etc.

Such illumination can also be remote illumination when said at least one light source 4 is coupled to at least one waveguide. This waveguide, also referred to as a light guide, is used to carry light from the point where it is injected into the guide to the substrate or to an area of the substrate (e.g. cavity, through-opening) close to the upper surface of this substrate. Such a light guide can be an optical fibre that allows any obstacles that can arise in the substrate to be bypassed, for example between the electroluminescent element and the region of the substrate close to the upper surface of this substrate, through which the light will escape. In this alternative embodiment, it is thus the light that is brought, via the waveguide, from the electroluminescent element to this area of the substrate to be illuminated.

In such a configuration, a first end of the waveguide is coupled to the light source 4 and a second end of this waveguide can be arranged in:
a cavity which can be a blind opening made in the lower surface of the substrate of this first layer 10; or
a through-opening extending through the thickness of the substrate of the first layer 10 and opening, at its two ends, respectively onto the upper and lower surfaces of this substrate and thus of the first layer 10. This second end can thus project from the upper surface of the substrate or of this first layer 10 or from the visible face 20a of the dial 2a in order, for example, to form a graphic representation of this dial 2a such as, for example, a reference element such as an index, a numeral, a dot, or a line, etc.

In this context, indirect illumination can be achieved by a single light source 4 included on the lower surface of the substrate of this first layer 10 by being coupled to a plurality of waveguides whose second ends are arranged in:
cavities each emitting light radiation from this light source 4, this radiation escaping to the outside of the dial 2a via the visible face 20a, thus allowing at least one graphic representation to be viewed in the dark. In this context, this graphic representation included in or on the visible face 20a of the dial 2a, or the upper surface of the substrate, is preferably opaque; and/or
through-openings projecting or not projecting from the upper surface of this substrate in order to form reference elements such as an index, line or even a dot, and each emitting light radiation from this light source 4.

In this first layer 10, the reporting module 4 is applied/fastened to the lower surface of the substrate of this first layer 10, in a cavity or on an internal wall of a previously mentioned through-opening, by printing or evaporation. In other words, the light source of this module 4 is applied/fastened to the lower surface of the substrate of this first layer 10, in a cavity or on an internal wall of a previously mentioned through-opening, by printing or evaporation.

In this first layer 10, the receiver element 23 is arranged in/on this substrate in order to be able to receive acoustic waves present in the enclosure of the case of the watch 1. This receiver element 23 can be arranged on or under the upper surface of this substrate forming the first layer 10. When arranged in the substrate, this receiver element 23 is positioned in a blind cavity formed in this upper surface. In an alternative embodiment, it can be arranged in a blind cavity made in the lower surface of this substrate having this upper surface as its bottom. In this configuration, the acoustic waves propagating in the dial 2a, 2b and in the visible face 20a can be measured by said receiver element 23. This substrate can further comprise a through-hole connecting the upper and lower surfaces together and in which the receiver element 23 can be arranged.

It should also be noted that the lower surface of this first layer 10 can be self-adhesive so that it can be assembled with the second layer 11.

In this stack 9a, the second layer 11 comprises a substrate including the photovoltaic module 5. Such a substrate is preferably flexible or pliable. The substrate of the second layer 11 can be a film on which the photovoltaic module 5 is arranged, or it can be made of a material belonging to the polymer family.

In this second layer 11, the photovoltaic module extends preferentially over the whole of a so-called active area of the upper surface of this substrate. This active area is a portion of the upper surface of the substrate which is able to receive light from the lower surface of the first layer 10 of the dial 2a. This light, which has passed through all or part of the first layer 10, comes from the external environment of the dial 2a, and thus of the watch 1, in this case mainly from solar radiation when it is of natural origin.

It should be noted that the photovoltaic module 5 is applied to the upper surface of this substrate using inkjet or screen printing processes or using thermal evaporation printing processes. Reference will also be made here to a second layer 11 comprising a printed photovoltaic module 5, in particular, a photovoltaic module 5 printed on the substrate of the second layer 11.

It should be noted that once the photovoltaic module 5 has been applied to the substrate, a layer of a self-adhesive substance can be deposited on all or part of the upper surface and/or of the lower surface of the substrate. In these circumstances, the second layer 11 can be a self-adhesive layer which helps to facilitate its assembly with the other layers, in particular with the first layer 10 and/or the third layer 12 of this stack 9a.

In the stack 9a, this third layer 12 further comprises a preferably flexible or pliable substrate, including the electrical energy accumulator 6 of the autonomous determination device 3. This substrate of the third layer 12 can be a film on which the accumulator 6 is arranged. Such a substrate can be made of a material belonging to the polymer family.

This accumulator 6 can be a lithium battery or a semiconductor battery. Such a battery 6 is applied to the upper surface of this substrate using processes known in the prior art, such as:
printing processes on a flexible polymer substrate, when this involves a lithium battery for example; or
three-dimensional printing processes, for example when this involves a semi-conductor battery such as a lithium-metal semi-conductor battery.

Reference will also be made here to a third layer 12 comprising a printed electrical energy accumulator 6, in particular, an electrical energy accumulator 6 printed on the substrate of the third layer 12.

Such processes make it possible to obtain a third layer 12 comprising this accumulator 6 which is flexible and ultra-thin.

Moreover, it should be noted that once the accumulator 6 has been applied to the substrate, a layer of a self-adhesive substance can be deposited on all or part of the upper surface and/or of the lower surface of this substrate. In these circumstances, the third layer 12 can be a self-adhesive layer which helps to facilitate its assembly with the other layers, in particular with the second layer 11 and/or the fourth layer 13 of this stack 9a.

It should be noted that this accumulator 6 is used to store the electrical energy produced by the photovoltaic module 5 and to release it on demand to power the determination device 3, in particular the reporting module 4 and said at least one receiver element 23.

In this stack 9a, this fourth and final layer 13 forms the hidden face of the dial 2a. Such a fourth layer 13 is formed by a preferably flexible or pliable substrate, including the control unit 7. Such a substrate for the fourth layer 13 can be, for example, a flexible PCB on which this control unit 7 is arranged, in particular on the upper surface of this PCB and thus of the substrate. In this context, the control unit 7 can be constructed on this upper surface of the substrate using three-dimensional printing processes or polymer printing processes.

In this fourth and final layer 13, the receiver element 23 is arranged in/on this substrate in order to be able to receive acoustic waves present in the enclosure of the case of the watch 1. This receiver element 23 can be arranged on or under the lower surface of this substrate forming this fourth layer 13. When arranged in the substrate, this receiver element 23 is positioned in a blind cavity formed in this lower surface. In an alternative embodiment, it can be arranged in a blind cavity made in the upper surface of this substrate having this lower surface as its bottom. In this configuration, the acoustic waves propagating in the dial 2a, 2b and in the hidden face 20b can be measured by said receiver element 23. This substrate can further comprise a through-hole connecting the upper and lower surfaces together and in which the receiver element 23 can be arranged.

In the second alternative embodiment, the stack 9b forming the dial 2b comprises three thin layers 10, 11, 14, joined together. It should be noted that this second alternative embodiment differs from the first alternative embodiment in that it comprises three layers 10, 11, 14 instead of four layers 10, 11, 12, 13, as in the first alternative embodiment. In this second alternative embodiment, the electrical energy accumulator 6 of the determination device 3 is now included in the third and final layer 14 of this stack 9b with the control unit 7.

Such a third and final layer 14 of this stack 9b, forming the hidden face of the dial 2b, consists of a preferably flexible or pliable substrate, on which are constructed, preferably on the upper surface of this substrate, the battery 6 and the electronic circuit 8 constituting the control unit 7. The accumulator 6 and the control unit 7 can be constructed on this upper surface of the substrate using three-dimensional printing processes or polymer printing processes. It should be noted that such a substrate can be, for example, a flexible PCB.

In this third and final layer 14 of this second alternative embodiment, the receiver element 23 is arranged in/on this substrate in order to be able to receive acoustic waves present in the enclosure of the case of the watch 1. This receiver element 23 can be arranged on or under the lower surface of this substrate forming the third layer 14. When arranged in the substrate, this receiver element 23 is positioned in a blind cavity formed in this lower surface. In an alternative embodiment, it can be arranged in a blind cavity made in the upper surface of this substrate having this lower surface as its bottom. In this configuration, the acoustic waves propagating in the dial 2a, 2b and in the hidden face 20b can be measured by said receiver element 23. This substrate can further comprise a through-hole connecting the upper and lower surfaces together and in which the receiver element 23 can be arranged.

In summary, in this second alternative embodiment, the stack 9b comprises:
a first layer 10 forming the visible face 20a of the dial 2b including said at least one receiver element 23 and/or the reporting module 4;
a second layer 11 including the photovoltaic module 5; and
the third layer 14 forming the hidden face 20b of the dial 2b including said at least one receiver element 23 and/or the accumulator 6 and the control unit 7.

It should be noted that in this second alternative embodiment, the first and second layers 10, 11 are similar to those of the first alternative embodiment of stack 9a.

Furthermore, with reference to FIGS. 3 and 5, the electronic circuit 8 of the control unit 7 comprises first connection elements 15a which are connected to connection elements 16 connecting:
the reporting module 4 for managing the operation of this module 4, in particular for broadcasting a message relating to the determined acoustic event; and
said at least one receiver element 23 to contribute to determining the acoustic event.

This electronic circuit 8 further comprises second connection elements 15b connected to first connection elements 17a of the accumulator 6.

Moreover, it should be noted that the event sensors of the determination device 3, mentioned above, are preferably arranged in the first layer 10 and/or the final layer 13, 14 of the stack 9a, 9b of layers and are connected to the control unit 7 of this device 3.

In a third alternative embodiment not shown, the stack of thin layers forming the dial comprises two interconnected layers. It should be noted that this third alternative embodiment differs from the second alternative embodiment in that it comprises two layers instead of three layers 10, 11, 14, as in the second alternative embodiment. In this third alternative embodiment, the photovoltaic module 5 of the autonomous determination device 3 is now included in the first layer and in particular on the lower surface of the substrate forming this first layer. This photovoltaic module 5 can be applied to this lower surface of the substrate of this first layer using inkjet or screen printing processes or using thermal evaporation printing processes. It should thus be noted that this first layer is therefore similar to the first layers 11 of the first and second alternative embodiments, with the exception that in this third alternative embodiment, the first layer additionally comprises the photovoltaic module.

In the third alternative embodiment, and similarly to the second alternative embodiment, the electrical energy accumulator 6 of the autonomous determination device 3 is included in the second and final layer of this stack with the control unit 7. Such a second layer forming the hidden face of the dial, consists of a preferably flexible or pliable substrate, on which are constructed, preferably on the upper surface of this substrate, the battery 6 and the electronic circuit 8 constituting the control unit 7. This accumulator 6 and the control unit 7 can be constructed on the upper surface of the substrate using three-dimensional printing processes or polymer printing processes. It should be noted that such a substrate can be, for example, a flexible PCB.

In summary, in this third alternative embodiment, the stack of layers thus comprises:
a first layer forming the visible face 20a of the dial including said at least one receiver element 23 and/or the reporting module 4 and the photovoltaic module 5; and
a second layer forming the hidden face 20b of the dial including said at least one receiver element 23 and/or the accumulator 6 and the control unit 7.

In the final layers 13, 14 of the various alternative embodiments, the transmitter-receiver module 23 is applied/fastened to the lower or upper surface of the substrate of these layers, in a cavity or on an internal wall of a previously mentioned through-opening, by printing or evaporation.

Thus, in this dial 2a, 2b, the determination device 3 comprises the receiver element 23 which converts the acoustic wave received into an electrical signal which is transmitted to the control unit 7. Therefore, when at least one acoustic wave is generated by a timepiece component or by a timepiece mechanism, an electrical signal comprising data relating to one or more acoustic waves received is then transmitted by the receiver element 23 to the control unit 7. This control unit 7 then processes these data on the basis of the algorithm for determining an acoustic event. Such processing allows the acoustic event to be identified as a function of, in particular, the features of at least one acoustic wave picked up by the receiver element 23, namely: the period, frequency, wavelength, acoustic power, acoustic intensity, acoustic pressure and/or duration of said at least one acoustic wave.

Determining an acoustic event can allow this dial 2a, 2b to implement various functions of this watch. For example, a function of this watch can correspond to the detection of an impact suffered by a timepiece component such as a case component, such as the middle, the crystal or the crown of the watch 1, which can lead to a loss of timekeeping accuracy. More specifically, the operation of the mechanism can be disrupted by impacts to the watch. As a result, although a watch's internal clock provides an accurate indication of the current time, the hour and minute hands provide a distorted indication of this current time, because the gears have skipped a few steps due to the effect of the impact to the watch. It is therefore necessary to resynchronise the position of the hour and minute hands. Thus, as part of this function, the control unit 7 can generate a visual, vibration and/or audio message depending on this event, signalling this loss of precision by controlling/driving the reporting module 4.

Other functions of the watch using the determination of an acoustic event can include, in a non-limitative and non-exhaustive manner:
a passing (or non-passing) of the date indicator can be detected by the receiver element 23. A light source can then be used to signal the causal event;
a stop in a mechanism stop notch, for example in the hand-setting mechanism of the watch 1, can be detected by the receiver element 23. At least one light source can then be used to indicate the position in which the mechanism is located, for example the time correction position or the date indicator correction position;
a predefined impact sequence can be detected by the receiver element 23, for example in order to switch on or off a light source 4 or to modify its light colour;
a sequence of taps on the watch crystal 1 can be used to illuminate the dial 2a, 2b or to backlight the hands in order to make the time visible at night, another sequence of taps can be used to modify the light colour of said at least one active light source;
a deviation in a frequency monitored by the receiver element 23 can be signalled by the use of at least one light source. This variation in frequency can indicate a current or future malfunction.

It goes without saying that this invention is not limited to the embodiments described above and that various simple alternatives and modifications can be considered by a person skilled in the art without leaving the scope of the invention as defined by the accompanying claims.

1. A dial of a watch comprising an autonomous device for determining an acoustic event, such a dial comprising a visible face and a hidden face, said dial being formed by a stack of thin layers of material extending between these two faces, each of said layers comprising one or more of the functional elements included in said device:
at least one receiver element for receiving at least one acoustic wave originating from the watch;
a module for reporting the acoustic event;
a stand-alone power supply unit; and
a control unit for managing the operation of said reporting module and said at least one receiver element for receiving at least one acoustic wave.

2. The dial according to claim 1, wherein said at least one receiver element comprises a pressure microphone or a pressure-gradient microphone.

3. The dial according to claim 1, wherein the module for reporting the acoustic event comprises:
at least one element capable of generating a light signal;
at least one element capable of generating a vibration signal; and/or
at least one element capable of generating a sound signal.

4. The dial according to claim 1, wherein the stack of thin layers of material comprises a first layer provided with the visible face of the dial, and the first layer comprising said at least one receiver element and said reporting module.

5. The dial according to claim 1, wherein said at least one receiver element is arranged in a cavity formed in the hidden face of this dial.

6. The dial according to claim 1, wherein said first layer is configured such that light radiation, in particular solar radiation, can fully or partially pass therethrough.

7. The dial according to claim 1, wherein said first layer is wholly or partially transparent or translucent.

8. The dial according to claim 1, wherein the stack of thin layers of material includes a second layer comprising a photovoltaic module constituting the stand-alone power supply unit.

9. The dial according to claim 1, wherein the stack of thin layers of material includes a second layer comprising a photovoltaic module constituting the stand-alone power supply unit, the second layer comprising a substrate on which the photovoltaic module is printed.

10. The dial according to claim 1, wherein the stack of thin layers of material includes a second layer comprising a photovoltaic module constituting the stand-alone power supply unit, said photovoltaic module being arranged on an active area of said second layer, said area being configured to receive light rays originating from the first layer of the stack of thin layers of material.

11. The dial according to claim 1, wherein the stack includes a third layer comprising an electrical energy accumulator constituting the stand-alone power supply unit.

12. The dial according to claim 1, wherein the stack includes a third layer comprising an electrical energy accumulator constituting the stand-alone power supply unit, the third layer comprising a substrate on which the electrical energy accumulator is printed.

13. The dial according to claim 1, wherein the stack comprises a fourth layer forming a hidden face of the dial comprising the control unit.

14. The dial according to claim 1, wherein the stack comprises a third layer comprising a hidden face of the dial comprising the control unit and an electrical energy accumulator constituting the stand-alone power supply unit.

15. The dial according to claim 1, wherein the first layer is rigid compared to the other layers in the stack of thin layers of material, which are flexible.

16. The dial according to claim 1, wherein said visible and hidden faces are flat or domed.

17. A watch comprising the dial according to claim 1.

18. A watch according to claim 17, further comprising a mechanical, electronic or electromechanical horological movement.
